(19) United States
(12) Patent Application Publication
(10) Pub. No.: US 2011/0090157 A1
(43) Pub. Date: Apr. 21, 2011

(54) Touch Display Apparatus and Manufacturing Method Thereof

(75) Inventors: Shih-Ying Chen, Taipei County (TW); Cheng-Yi Lee, Taipei County (TW); Hsih-Chin Liu, Taipei County (TW)

(73) Assignees: INVENTEC APPLIANCES (SHANGHAI) CO. LTD., Shanghai (CN); INVENTEC APPLIANCES CORP., Taipei County (TW)

(21) Appl. No.: 12/880,535

(22) Filed: Sep. 13, 2010

(30) Foreign Application Priority Data
Oct. 15, 2009 (CN) 200910206831.3

(51) Int. Cl. G06F 3/041; H05K 3/00

(52) U.S. Cl. 345/173; 156/60; 216/13; 156/242; 156/256

(57) ABSTRACT

The present invention includes a touch display apparatus and a manufacturing method thereof. The touch display apparatus includes a display unit, a first transparent substrate, a first electrically conductive layer, a second electrically conductive layer and a second transparent substrate. The display unit is disposed at a base of the touch display apparatus. The first transparent substrate has a light guiding element and is disposed on the display unit. The first electrically conductive layer is disposed on the first transparent substrate. The second electrically conductive layer is disposed on the second transparent substrate and between the second transparent substrate and the first electrically conductive layer. The touch display apparatus may include spacers disposed on a downward surface of the second electrically conductive layer. Because there is the light guiding element, an additional light guiding element isn't needed, thereby not only simplifying the manufacturing process but also enhancing the display effect.

### BACKGROUND OF THE INVENTION

1. Field of the Invention

The present invention relates to a touch display apparatus and a manufacturing method thereof, and more particularly to a touch display apparatus and its manufacturing method having a simplified manufacturing process and enhancing the optical effect of the display panel.

2. Description of Related Art

So far, touch panels have been used extensively in various electronic devices including portable light, thin, short and compact electronic devices such as personal digital assistants (PDA), electronic dictionaries, watches, calculators or notebook computers. The use of touch panels is very convenient, without requiring any additional input device such as a keyboard, so as to reduce the weight of the device significantly. According to the current market requirements, the lighter and the better portability, the higher is the product competitiveness in the market. Touch panels can be divided by the structure and sensing form into resistive touch panels, capacitive touch panels, optical touch panels, electromagnetic panels and so on.

In the design of a touch panel such as a resistive touch panel generally used in a flat display apparatus is mostly comprised of two layers, a polyethylene teteraphthlate (PET) film layer and a glass layer respectively coated with indium tin oxide (ITO), and a spacer distributed therebetween. With reference to FIG. 1 for a cross-sectional view of a conventional flat display apparatus, the flat display apparatus is a front-light reflection type display apparatus comprising a display panel 150, a front-light panel 130 disposed on the top of the display panel 150, a touch panel module 120 dispose on the top of the front-light panel 130, a light source 110 disposed at a lateral side of the front-light panel 130, and a casing 100 for containing the front-light panel 130, the display panel 150 and the light source 110. The touch panel module 120 includes a transparent glass layer 125, an upward surface of which is coated with an indium tin oxide (ITO) layer 124, wherein the ITO is a transparent substance. A layer 123 comprising spacers 126 is disposed on the ITO layer 124. The touch panel module 120 further includes a PET film layer 121, a downward surface of which is also coated with an ITO layer 122. The PET film layer 121 and a glass layer 125 are adhered together, and spacers 126 are distributed between the PET film layer 121 and the glass layer 125. When the touch panel is used, a pressure is applied to a certain point of the PET film layer 121, such that the ITO layer 122 at this point is touched with the ITO layer 124 to constitute a connection of electric current, so as to generate an electric signal used as an input signal. The touch panel module 120 is attached onto the front-light panel 130 or the casing 100. After the light source 110 is guided by the front-light panel 130 and projected onto the display panel, the light source 110 is passed through the front-light panel 130, the glass layer 125, the ITO layer 124, the ITO layer 122 and the PET film layer 121 before passing to the outside. Since the number of penetrating layers is relatively large, the brightness is insufficient or the color is relatively dark. As a result, the display effect will be poor.

In the design of the conventional touch panels, the touch panel module and the display module are designed independently, and thus the conventional touch panels come with a large number of layers, not just requiring a complicated manufacturing process and having a difficulty of reducing the thickness only, but also causing a low light transmission efficiency or a poor optical effect of displaying colors.

### SUMMARY OF THE INVENTION

An object of the present invention is to provide a touch display apparatus and a manufacturing method thereof for solving the existing technical problems of the touch display having a complicated structure design and a poor display effect because of too many layers disposed.

At least according to the object of the present invention, a touch display apparatus comprising a display unit, a first transparent substrate, a first electrically conductive layer, a second transparent substrate, and a second electrically conductive layer is provided. In the touch display apparatus, the display unit is disposed at a base of the touch display apparatus. The first transparent substrate has a light guiding element for scattering a projected light beam to the display unit. The first electrically conductive layer is disposed on the first transparent substrate and has an upward surface. The second electrically conductive layer is disposed on the second transparent substrate and between the second transparent substrate and the first electrically conductive layer, and the second electrically conductive layer has a downward surface. An interstructure is disposed between the downward surface of the second electrically conductive layer and the upward surface of the first electrically conductive layer.

In an embodiment, the touch display apparatus further comprises spacers disposed on the downward surface of the second electrically conductive layer. In another embodiment, the touch display apparatus further has a light emitting unit disposed by an end of the first transparent substrate for emitting the projected light beam.

At least according to the object of the present invention, a method of manufacturing a touch display apparatus is further provided, which includes the following steps in an embodiment. In this embodiment, a first transparent substrate and a second transparent substrate are respectively provided. A light guiding element is then formed in the first transparent substrate, wherein the light guiding element is used for scattering a projected light beam. Then, a first electrically conductive layer is disposed on the first transparent substrate, wherein the first electrically conductive layer has an upward surface. With respect to the second transparent substrate, a second electrically conductive layer is disposed on the second transparent substrate and between the second transparent substrate and the first electrically conductive layer, wherein the second electrically conductive layer has a downward surface. Moreover, an interstructure is disposed between the downward surface and the upward surface.

In another embodiment the interstructure is disposed between a periphery of the downward surface of the second electrically conductive layer and a periphery of the upward surface of the first electrically conductive layer. Also, in an embodiment, the method further comprises a step of disposing spacers on the downward surface of the second electrically conductive layer. Still in an embodiment, the first transparent substrate is disposed on a display unit, and the light guiding element is used for uniformly scattering the projected light beam to the display unit.

Moreover, the method may further comprise a step of disposing a light emitting unit by an end of the first transparent substrate for emitting the projected light beam.

From the above, according to the touch display apparatus and the manufacturing method thereof of the present invention, there is no need to additionally dispose a light guiding element corresponding to the display module, thereby not only simplifying the manufacturing process but also enhancing the optical effect of the touch display apparatus.

### BRIEF DESCRIPTION OF THE DRAWINGS

FIG. 1 illustrates a schematic diagram of a conventional flat display apparatus;

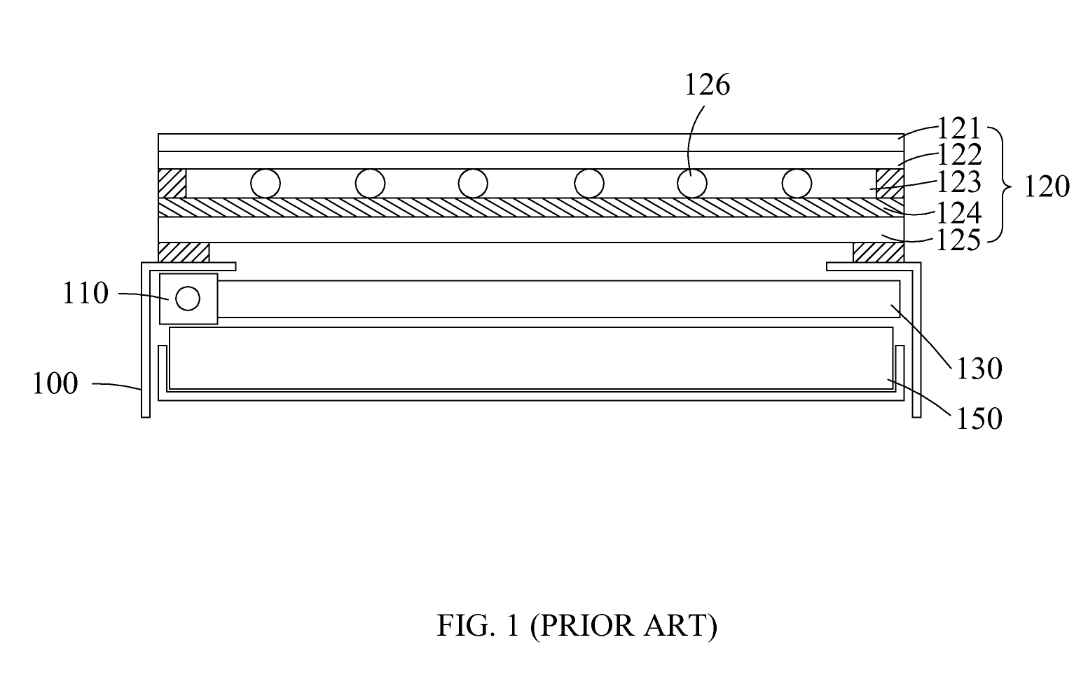

FIG. 2 illustrates a schematic diagram of a touch display apparatus in accordance with a first embodiment of the present invention;

FIG. 3 illustrates a structure schematic diagram of a first transparent substrate of the touch display apparatus in accordance with the first embodiment of the present invention;

FIG. 4 illustrates a structure schematic diagram of a second transparent substrate of the touch display apparatus in accordance with the first embodiment of the present invention;

FIG. 5 illustrates a schematic diagram of a touch display apparatus in accordance with a second embodiment of the present invention; and

FIG. 6 illustrates a flowchart of a method of manufacturing a touch display apparatus in accordance with an embodiment of the present invention.

### DETAILED DESCRIPTION OF THE PREFERRED EMBODIMENTS

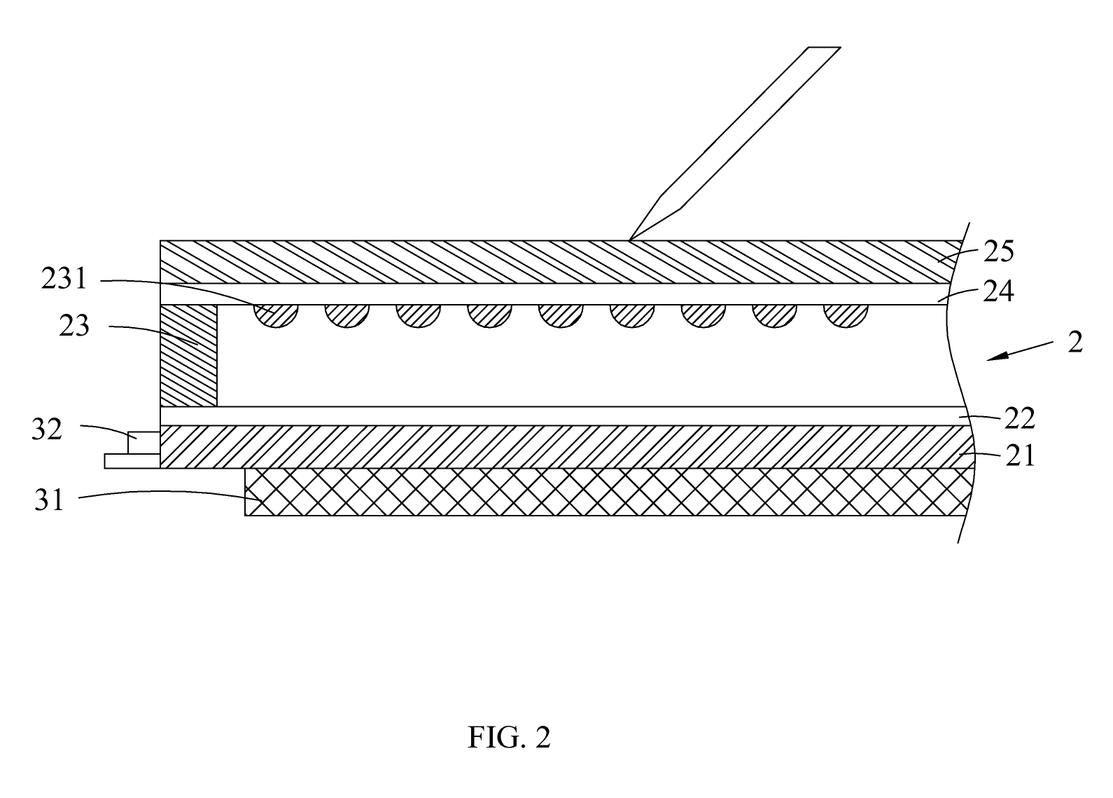

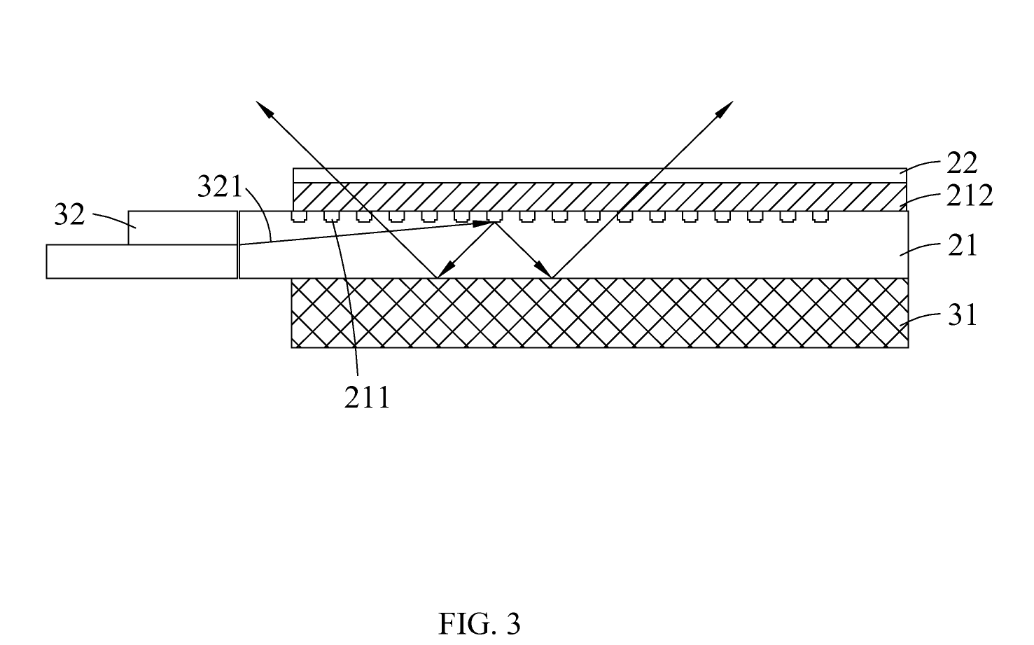

FIGS. 2 and 3 respectively illustrate a schematic diagram of a touch display apparatus in accordance with a first embodiment of the present invention and a structure schematic diagram of a first transparent substrate thereof. Referring to FIGS. 2 and 3, a display unit 31 is disposed at a base of a touch display apparatus 2. The touch display apparatus 2 further comprises a first transparent substrate 21, a first electrically conductive layer 22, a second electrically conductive layer 24, a second transparent substrate 25, and a light emitting unit 32. The light emitting unit 32 is disposed by an end of the first transparent substrate 21 and may be made of light emitting elements such as one or a plurality of light emitting diodes (LED) or cold cathode fluorescent lamp (CCFL) tubes. The light emitting unit 32 is capable of emitting a projected light beam 321 for illuminating the display unit 31.

The first transparent substrate 21 may be made of a material of a polyethylene teteraphthlate (PET) film. In order to make the first transparent substrate 21 have a light guiding effect, a light guiding element 211 with a groove shape may be formed on or close to the surface of the first transparent substrate 21 by laser engraving, printing, etching, cutting, injection molding, or applying a microstructure coating. The light guiding element 211 may comprise, for example, polymethyl methacrylate (PMMA) or glass. Besides, in order to intensify the hardness of the first transparent substrate 21 for preventing from being scratched, if needed, a transparent hardened layer 212 may be disposed by one side of the first transparent substrate 21 using a coating method.

The first electrically conductive layer 22 may be made of indium tin oxide (ITO), and can be sputtered on the first transparent substrate 21 and located on the surface of the light guiding element 211 by a physical vapor deposition (PVD) method. In addition, after the first electrically conductive layer 22 is disposed on the first transparent substrate 21, the first electrically conductive layer 22 may be performed with an etching treatment and disposed with a plurality of electrically conductive circuits by a silver paste coating method for transmitting an electric signal.

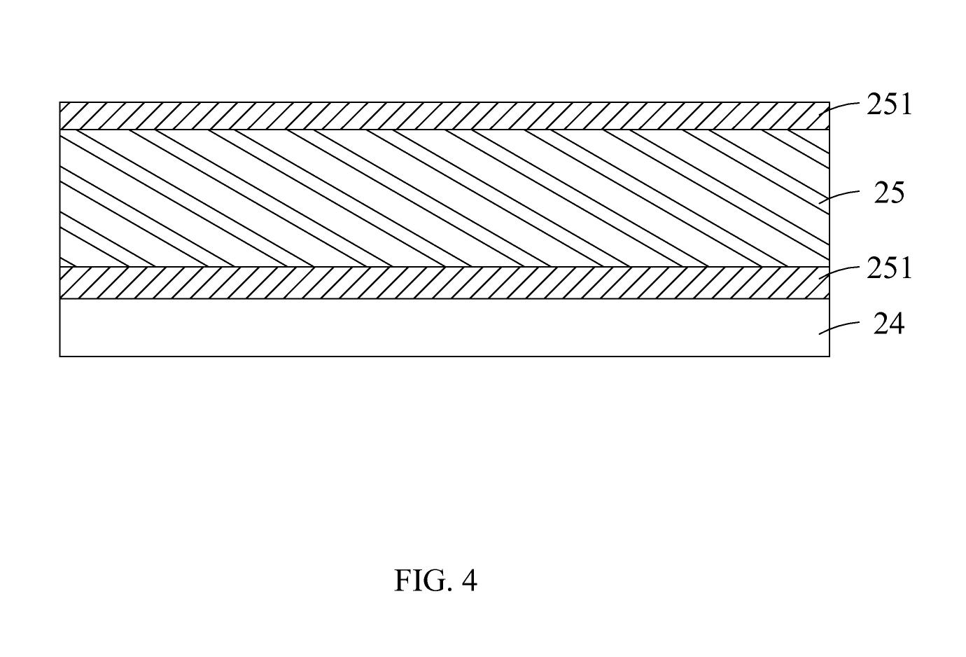

The second transparent substrate 25 may be made of a material comprising polymethyl methacrylate (PMMA), a PET film, glass or polycarbonate (PC). In order to intensify the hardness of the second transparent substrate 25 for preventing from being scratched, if needed, a transparent hardened layer 251 may be disposed by two sides of the second transparent substrate 25 using the coating method, as shown in FIG. 4. The second electrically conductive layer 24 may be made of the ITO and can be coated on the second transparent substrate 25 by a plating method.

Referring to FIG. 2 again, a periphery of the downward surface of the second electrically conductive layer 24 and a periphery of the upward surface of the first electrically conductive layer 22 are connected by an interstructure 23. The interstructure 23 can also be called an intermediate or middle structure. Furthermore, in this embodiment, spacers 231 are disposed on the downward surface of the second electrically conductive layer 24 to separate the second electrically conductive layer 24 from the first electrically conductive layer 22 for preventing the first electrically conductive layer 22 and the second electrically conductive layer 24 from attaching together, resulting that both always have an electric conductance.

A light guiding effect can be achieved because a light guiding element 211 is disposed on the first transparent substrate 21. After the projected light beam 321 is emitted from the light emitting unit 32, the light radiating to the light guiding element 211 has a total reflection in an interface due to its optical property. Therefore, the projected light beam 321 can be uniformly scattered to the surface of the display unit 31 so as to generate a secondary refraction. Because the light of such secondary refraction does not achieve a total reflection angle, it will pass through the light guiding element 211, the spacer 231 and the second transparent substrate 25 and then be emitted to the outside for providing a user to view the image information shown by the display unit 31.

When the user presses the second transparent substrate 25 by a finger or a touch pen to make it concave, a pressed position of the second electrically conductive layer 24 will be dented downward so as to contact electrically with the first electrically conductive layer 22 below the he second transparent substrate 25, thereby generating a voltage variation which then be transferred into an digital signal by an A/D converter. After calculating, a coordinate position of the touched point can be obtained.

By means of providing the light guiding element 211 on the first transparent substrate 21, unlike the display unit made by the existing technology, there is no necessity of depositing a dedicated light guiding element in accordance with the present invention. Consequently, the deposited layers can be reduced so as to simplify the manufacturing process, and the shortcomings of the optical image displayed by the display unit having an insufficient brightness or a relatively dark color caused by the refraction and reflection effect of each layer can be overcome, thereby further enhancing the quality of the optical image.

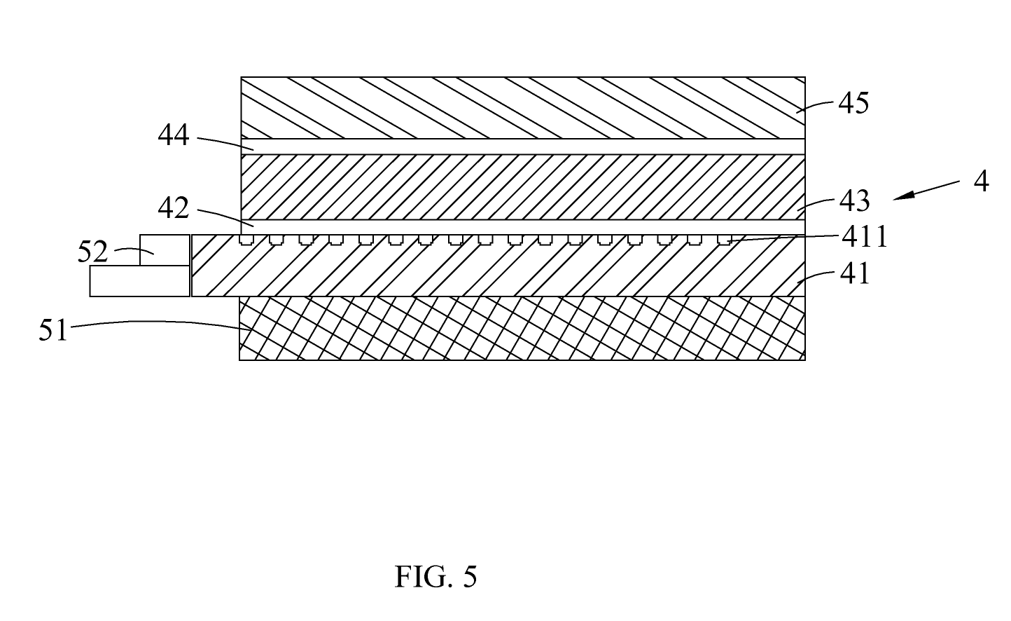

FIG. 5 illustrates a schematic diagram of a touch display apparatus in accordance with a second embodiment of the present invention. Referring to FIG. 5, a display unit 51 is disposed at a base of a touch display apparatus 4. Besides, the touch display apparatus 4 further comprises a first transparent substrate 41, a first electrically conductive layer 42, an interstructure 43, a second electrically conductive layer 44, and a second transparent substrate 45, and may further comprise a light emitting unit 52. Wherein, the first transparent substrate 41 has a light guiding element 411. In this embodiment, the first transparent substrate 41 and the first electrically conductive layer 42 are the same as those described in the first embodiment, and are thus not again described. The light guiding element 411 may comprise, for example, polymethyl methacrylate (PMMA) or glass. The difference between this embodiment and the first embodiment is that the interstructure 43 can be a glass layer because the touch display apparatus in this embodiment belongs to a capacitive touch display apparatus. The second electrically conductive layer 44 is formed on one side of the interstructure 43 in opposition to the first electrically conductive layer 42 by a sputtering method. Moreover, the second transparent substrate 45 may be a hardening treatment layer. The hardening treatment layer is a thin layer of silicon dioxide, and its hardness value can be more than 7 Mohs' hardness number (VHN), capable of preventing form being scratched. The working theory of the touch display apparatus in this embodiment is to establish a uniform electric field on the glass layer. The purpose of touch control can be achieved by sensing a weak current in human body

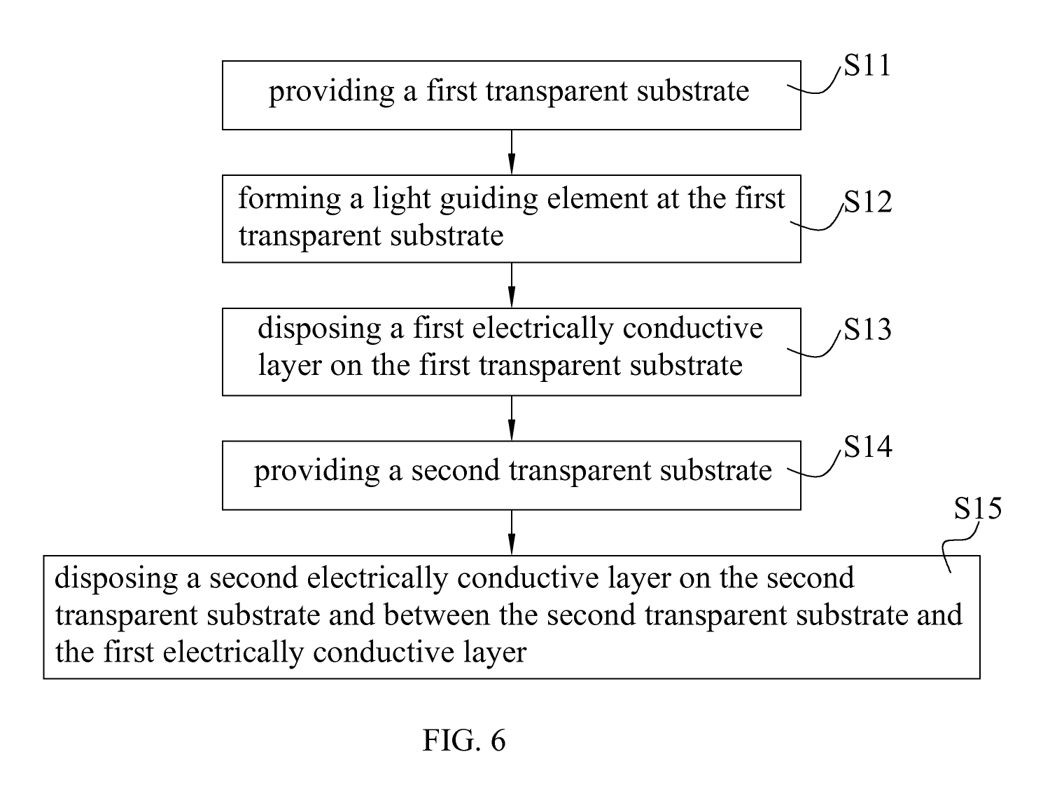

FIG. 6 illustrates a flowchart of a method of manufacturing a touch display apparatus in accordance with an embodiment of the present invention, comprising the steps of:

S11: providing a first transparent substrate;

S12: forming a light guiding element at the first transparent substrate;

S13: disposing a first electrically conductive layer on the first transparent substrate, the first electrically conductive layer having an upward surface;

S14: providing a second transparent substrate; and

S15: disposing a second electrically conductive layer on the second transparent substrate and between the second transparent substrate and the first electrically conductive layer, the second electrically conductive layer having a downward surface.

The light emitting unit can be formed by laser engraving, printing, etching, cutting, injection molding, or applying a microstructure coating so as to make the first transparent substrate have the light emitting unit.

Wherein, the first transparent substrate may be a PET film. The first electrically conductive layer may be made of ITO, and can be sputtered on the first transparent substrate by a PVD method. In order to intensify the hardness of the first transparent substrate for preventing from being scratched while a user operates or touches it, a transparent hardened layer may, if needed, be disposed by two sides of the first transparent substrate using the coating method.

The second transparent substrate may be made of a material comprising PMMA, a PET film, glass or PC. Wherein, in order to intensify the hardness of the second transparent substrate for preventing from being scratched, a transparent hardened layer may, if needed, be disposed by two sides of the second transparent substrate using the coating method.

Wherein, the first electrically conductive layer and the second electrically conductive layer can be further performed with an etching treatment and disposed with a plurality of electrically conductive circuits by a silver paste coating method for transmitting an electric signal.

If the touch display apparatus is a resistive touch display apparatus, the method of manufacturing a touch display apparatus further comprises a step of disposing an interstructure between a periphery of the downward surface of the second electrically conductive layer and a periphery of the upward surface of the first electrically conductive layer. Furthermore, another step of disposing spacers on the downward surface of the second electrically conductive layer is further comprised so as to obtain the resistive touch display apparatus.

If the touch display apparatus is a capacitive touch display apparatus, the method of manufacturing a touch display apparatus further comprises a step of disposing an interstructure which may be a glass layer between a periphery of the downward surface of the second electrically conductive layer and a periphery of the upward surface of the first electrically conductive layer, and a step of establishing a uniform electric field on the glass layer. The purpose of touch control can be achieved by sensing a weak current in human body

To sum up, the efficacy of the touch display apparatus and the manufacturing method thereof according to the present invention is to deposit a microgroove structure on a side of the transparent substrate such that the transparent substrate can have a light guiding effect. Therefore, the present invention can overcome the problems in the existing technology. For example, for the existing technology, if the light is desired to be uniformly scattered on the display unit, it is needed to deposit additionally a light guiding element, resulting in the problems of having a complicated structure design so as to increase the difficulty of the manufacturing process and having a poor image display effect due to too many layers.

While particular embodiments of the present invention have been shown and described, it will be obvious to those skilled in the art that, based upon the teachings herein, changes and modifications may be made without departing from this invention and its broader aspects. Therefore, the appended claims are intended to encompass within their scope of all such changes and modifications as are within the true spirit and scope of the exemplary embodiments of the present invention.

What is claimed is:

1. A touch display apparatus, comprising:
a display unit, disposed at a base of the touch display apparatus;
a first transparent substrate, disposed on the display unit, and having a light guiding element for scattering a projected light beam to the display unit;
a first electrically conductive layer, disposed on the first transparent substrate, and having an upward surface;
a second transparent substrate; and
a second electrically conductive layer, disposed on the second transparent substrate and between the second transparent substrate and the first electrically conductive layer, the second electrically conductive layer having a downward surface;
wherein an interstructure is disposed between the downward surface of the second electrically conductive layer and the upward surface of the first electrically conductive layer.

2. The touch display apparatus of claim 1, wherein the interstructure is disposed between a periphery of the downward surface of the second electrically conductive layer and a periphery of the upward surface of the first electrically conductive layer.

3. The touch display apparatus of claim 2, further comprising spacers disposed on the downward surface of the second electrically conductive layer.

4. The touch display apparatus of claim 1, further having a light emitting unit disposed by an end of the first transparent substrate for emitting the projected light beam.

5. The touch display apparatus of claim 1, wherein the light guiding element is formed by a method selected from a group consisting of laser engraving, printing, etching, cutting, injection molding, and applying a microstructure coating.

6. The touch display apparatus of claim 5, wherein the light guiding element is groove-shaped.

7. The touch display apparatus of claim 1, wherein the first electrically conductive layer and the second electrically conductive layer further include a plurality of electrically conductive circuits.

8. A method of manufacturing a touch display apparatus, comprising steps of:
providing a first transparent substrate;
forming a light guiding element at the first transparent substrate, and the light guiding element being used for scattering a projected light beam;
disposing a first electrically conductive layer on the first transparent substrate, the first electrically conductive layer having an upward surface;
providing a second transparent substrate;
disposing a second electrically conductive layer on the second transparent substrate and between the second transparent substrate and the first electrically conductive layer, the second electrically conductive layer having a downward surface; and
disposing an interstructure between the downward surface of the second electrically conductive layer and the upward surface of the first electrically conductive layer.

9. The manufacturing method of claim 8, wherein the interstructure is disposed between a periphery of the downward surface of the second electrically conductive layer and a periphery of the upward surface of the first electrically conductive layer.

10. The manufacturing method of claim 9, further comprising disposing spacers on the downward surface of the second electrically conductive layer.

11. The manufacturing method of claim 8, wherein the first transparent substrate is disposed on a display unit and the light guiding element is used for uniformly scattering the projected light beam to the display unit.

12. The manufacturing method of claim 8, further comprising disposing a light emitting unit by an end of the first transparent substrate for emitting the projected light beam.

13. The manufacturing method of claim 8, wherein the light guiding element is formed onto the first transparent substrate by a method selected from a group consisting of laser engraving, printing, etching, cutting, injection molding, and applying a microstructure coating.

14. The manufacturing method of claim 8, wherein the first electrically conductive layer and the second electrically conductive layer further include a plurality of electrically conductive circuits.
